(19) United States
(12) Patent Application Publication
(10) Pub. No.: US 2008/0055849 A1
(43) Pub. Date: Mar. 6, 2008

(54) Intelligent Outdoor Cabinet

(76) Inventor: Lin Hung Lee, Taipei (TW)

Correspondence Address: 3M INNOVATIVE PROPERTIES COMPANY, PO BOX 33427, ST. PAUL, MN, 55133-3427, US

(21) Appl. No.: 11/570,845

(22) PCT Filed: Jun. 17, 2005
(86) PCT No.: PCT/US05/21616

§ 371 Date: Dec. 18, 2006

(30) Foreign Application Priority Data
Jun. 29, 2004 (TW) 093119071

(51) Int. Cl. H05K 7/20

(52) U.S. Cl. 361/695; 361/688; 361/690

(57) ABSTRACT

An assembled telecommunication exchange cabinet, comprising a hollow body and a base, wherein the body comprises a set of front doors, left and right side doors, a top cover and a heat sink device. A plurality of inlets are disposed on the bottom surface of the body, and a telecommunication exchange device and terminal boards are accommodated inside the body. The body accommodates a Digital Subscriber Line Access Multiplexer and a telecommunication exchange device, which in turn, are connected to the corresponding terminal boards. The left and right side doors and the top cover can be subsequently opened separately after the set of front doors is opened. In addition, the heat sink device of the body is disposed under the top cover. The base of the cabinet is removeably attached to the body; and at least one battery holder is further disposed inside the base to accommodate at least one spare battery.

### FIELD OF THE INVENTION

The present invention relates to an assembled telecommunication exchange cabinet, in particular to a telecommunication exchange cabinet integrating a conventional phone exchange box with a Digital Subscriber Line Access Multiplexer (DSLAM).

### BACKGROUND INFORMATION

Since 2000, there has been an increasing need for broadband communications. The broadband service provided in the communication market includes cable modem based on cable television, the Asymmetric Digital Subscriber Line (ADSL) technology provided by the voice system service providers, and Fiber To The Home (FTTH). Generally, ADSL is transmitted by telephone lines

However, a traditional telecommunication exchange cabinet typically only provides a basic voice telecommunication service. Generally, in order to provide an ADSL broadband service, the telecommunication company has to install the Digital Subscriber Line Access Multiplexer in a Central Office and then connect it to an exchange cabinet, so that both voice and data signals can be carried and transmitted to subscribers. However, this kind of arrangement is well suited for subscribers within a distance of 4.3 kilometres from the Central Office, and typically provides a download speed of 512 KB. As for subscribers beyond this distance, it has been desirable to locate the DSLAM to the exchange box. However, when this arrangement is used to transmit data, if the Internet Service Provider (ISP) intends to raise the transmission speed to 6 MB, the costs will increase significantly, and the effective transmission distance thereof may be reduced.

Furthermore, taking into account the expensive land in urban areas, it may be expensive and difficult to install both the exchange box and the DSLAM at the same spot, which, in turn, requires an additional concrete foundation. Additionally, the heat-sinking effect of a typical conventional exchange box can be unsatisfactory and very noisy; thus it may not meet the requirements of environmental protection. Also, the space within the base of the box cannot accommodate other equipment, which is a waste of space.

### SUMMARY OF THE INVENTION

In view of the above issues, the applicant has developed an assembled intelligent telecommunication exchange cabinet, which integrates the conventional exchange cabinet with the DSLAM. Besides providing an ADSL broadband service, it provides a line switch function, an excellent heat-sinking function and generates low noise.

The present invention provides an assembled intelligent telecommunication exchange cabinet, which may not only be integrated with a conventional exchange box with the DSLAM, but can also transmit both ADSL and voice signals at the same time. It can also be installed on the existing concrete foundation of the exchange box to reduce the cost of broadband. In addition, the present invention provides an exchange cabinet with excellent heat-sinking effects and low noise, and further provides a modular base to accommodate different types of spare batteries.

To achieve the above objects, the exchange cabinet of one exemplary embodiment of the present invention employs a double layer structure, which chooses outdoor terminals for broadband transmission, and a maintenance-free valve regulated Ni—Cd battery or a valve regulated lead-acid battery suitable for outdoor operation, besides adopting a corresponding heat exchanger with an effective heat-sinking property. The temperature difference between the interior and exterior of the cabinet can be effectively controlled via the heat source transferring analysis. The active elements of the exchange cabinet of the present invention can be installed in outdoor cabinets to successfully solve the problem relating to many broadband installations, and also maintain the integration of the overall line configuration without changing the existing line supply regions.

To illustrate the following embodiments in detail with respect to the accompanying drawings, the technical properties of the present invention will be apparent to those skilled in the art to further implement the present invention accordingly. The following descriptions are only for illustrating the preferred embodiments, but not for restricting the invention. All the modifications and changes are made without departing from the scope of the claims.

### BRIEF DESCRIPTION OF THE DRAWINGS

FIG. 1 shows a perspective view of an exchange cabinets according to the present invention;

FIG. 2 shows the external structure thereof;

FIG. 3 shows a detailed exploded view thereof; and

FIG. 3A is an enlarged view of element 211 in FIG. 3.

### DETAILED DESCRIPTION

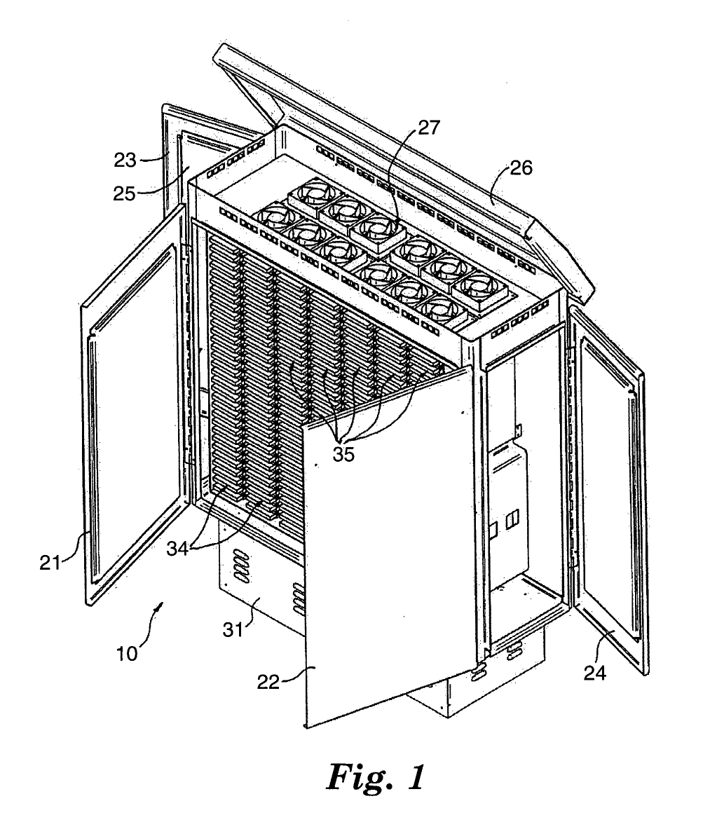

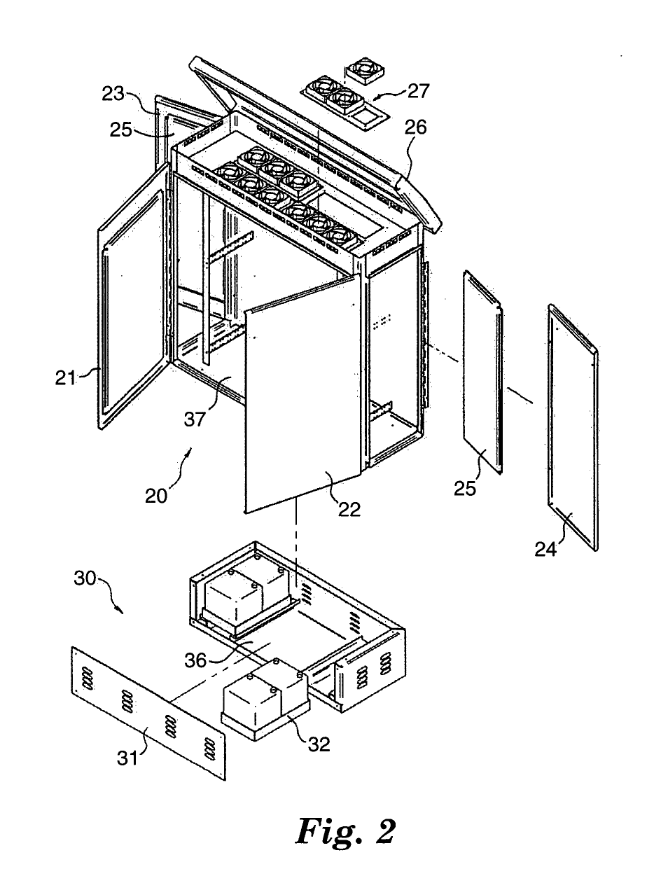

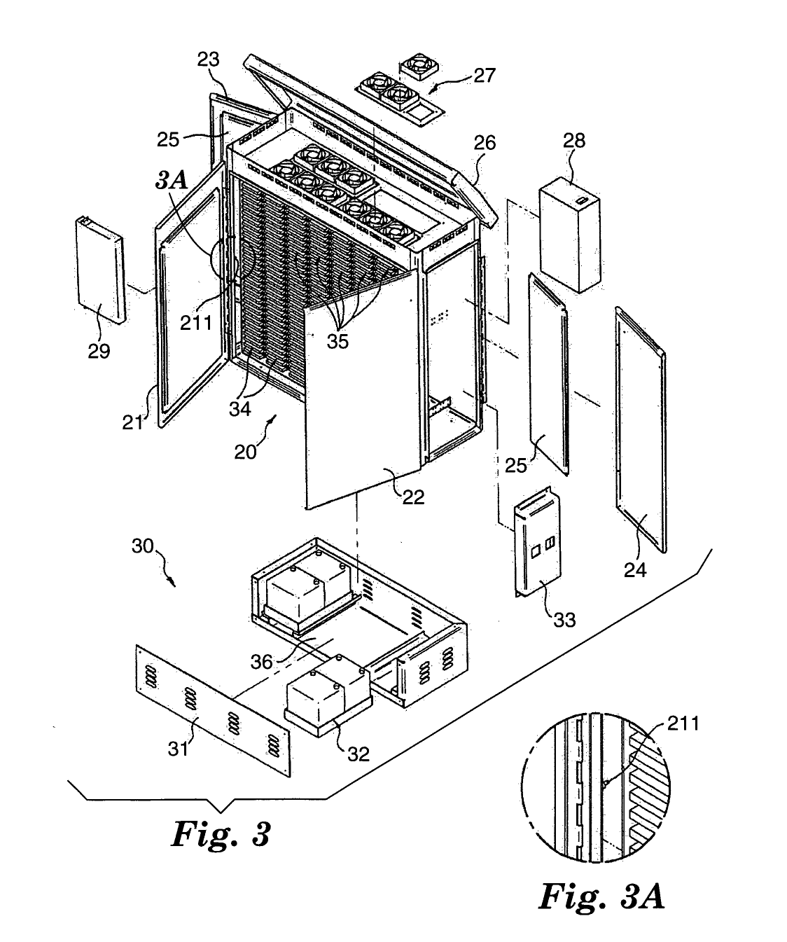

FIG. 1 shows a perspective view of an exemplary embodiment of the present invention; FIG. 2 and FIG. 3 show the external structure and a detailed exploded view thereof, respectively. An exchange cabinet 10 comprises a hollow body 20 and a base 30, wherein the body 20 and the base 30 can be separated from each other and assembled together. The base 30 is modularised, and the inside space arrangement thereof can be modified according to different requirements to accommodate one or more kinds of spare batteries, which in one embodiment comprises four 12V batteries. The spare battery serves to prevent the operation of the exchange cabinets 10 from being interrupted by power failure. The suitable spare battery herein may comprise a valve regulated lead-acid battery or a valve regulated Ni—Cd battery. The bottom surface 36 of the base 30 is disposed on the concrete foundation of the exchange box 10 (not shown), and the top end thereof is removeably attached to the bottom end 37 of the body 20.

On the bottom end 37 of the body 20 are further disposed one or a plurality of inlets (not shown) to introduce the cables from the bottom ground via the concrete foundation into the body 20, so as to interconnect with the exchange device (not shown) accommodated internally. In an exemplary embodiment, the external part of the body 20 comprises a left door panel 21 of the front door, a right door panel 22 of the front door, a left side door 23, a right side door 24 and a top cover 26. Each door panel and the top cover 26 can be pivotally connected and fixed to each side of the body 20 by conventional hinges, or with other proper mounting means. On the left and right side and the top end of the body 20, door latches 211 (referring to FIG. 3) are further installed to prevent the left and right side doors 23, 24 and the top cover 26 from being opened when the left and right door panels 21, 22 of the front door are closed. Latches 211 are positioned so as to be inaccessible when front door panels 21 and 22 are closed. To open side door 23, it is first necessary to unlock front doors 21 and 22 (by any known means) and then operate latch 211. Upon operating latch 211, side door 23 may be opened. A similar process is employed for right door 24. For the top cover 26, it may be opened after opening front doors 21 and 22. This is accomplished by securing top cover 26 with any suitable means (lock, latch, screw, bolt and the like), which is accessible only after front doors 21 and 22 are opened. This process is reversed to close and lock the cabinet. On the other hand, the left and right side doors 23, 24 and the top cover 26 are adapted to be opened after the set of front doors is opened. As for such arrangement, the sensors (not shown) within the body 20 only need to be disposed onto the set of front doors, which may greatly reduce the number of the sensors within the body 20.

The materials of the body 20 can be any desired material providing the desired properties, such as aluminium alloy and stainless steel to effectively isolate the heat generated by the sunlight. Further, a sandwiched layer 25 may be interposed between the left and right side doors 23, 24 to form a sandwiched aluminium board structure to enhance the isolation of the radiation heat from the sun. In addition, under the top cover 26 of the body 20, a set of heat-sink devices 27 are further disposed to dissipate the heat generated by the devices in the cabinet. The principle of air convection is utilised such that the cool air outside the exchange cabinet 10 enters from the bottom thereof, while the hot air exits from the top end thereof, so as to effectively control the temperature difference between the interior and the exterior of the cabinet 10. Therefore, when the heat-sink device 27 has a transmitted power of 200 W, the temperature of the exchange cabinet 10 may be lowered to less than 50° C. The heat-sink device 27 can be a fan assembly 27, or any other suitable means. The installation of the heat-sink device 27 is conducted by mounting the heat-sink device in place from the top end of the exchange cabinet 10, after opening the top cover 26. In one exemplary embodiment, the fan assembly 27 may also be a low noise heat-sinking fan assembly, which is mounted inside the exchange cabinet 10; thus, the noise level at a distance of 1.5 metres from the exchange cabinet 10 can be reduced to 60 dB, which is quieter than the 68 dB produced by DSLAM at the same distance, thereby reducing the environmental pollution.

Now referring to the exemplary embodiment illustrated in FIG. 3, the left side of the inside of the body 20 serves to accommodate the Digital Subscriber Line Access Multiplexer (DSLAM), which is further connected to two rows of the DSLAM terminal boards in the front of the body 20 so as to provide ADSL broadband service. The conventional voice exchange box device is connected to the other five rows of the telecommunication terminal boards 35 in the body 20 to provide a conventional voice telecommunication service. In one embodiment, two terminal boards may employ Cat.5 1800, 2100 or 2400-pair fully gel-filled weather-resisting terminal boards. In the embodiment illustrated, switching Mode DC power supplying device 28 is installed from the right side of the body 20 to convert an AC into 48V DC, which in turn, is supplied to the devices inside the body 20 through the distribution of the power distribution panel 33. In one exemplary embodiment, the dimension of the exchange cabinet 10 may also be designed as 1200 mm*1400 mm*470 mm; thus it can be mounted on the concrete foundation of the conventional exchange box, although suitable dimensions may be selected.

1. An assembled telecommunication exchange cabinet, comprising a hollow body and a base, wherein the body comprises a set of front doors, left and right side doors, a top cover and a heat-sink device; at least one inlet is disposed on the bottom surface of the body, and a telecommunication exchange device and terminal boards are accommodated inside the body, characterized in that:
the inside of the body is designed to accommodate a Digital Subscriber Line Access Multiplexer and a telecommunication exchange device connected to the corresponding terminal boards; the left and right side doors and the top cover are adapted to be opened after the set of front doors is opened; the heat-sink device of the body is disposed under the top cover; the base of the cabinet is removably attached to the body; and at least one battery holder is further disposed inside the base to accommodate at least one spare battery.

2. The assembled telecommunication exchange cabinet of claim 1, wherein the heat-sink device is adapted to be mounted from the top end of the body after the top cover is opened.

3. The assembled telecommunication exchange cabinet of claim 1, wherein the heat-sink device is a fan assembly.

4. The assembled telecommunication exchange cabinet of claim 2, wherein the heat-sink device is a fan assembly.

5. The assembled telecommunication exchange cabinet of claim 3, wherein the fan assembly is a low noise heat-sinking fan assembly, and the fan assembly is further mounted inside the assembled telecommunication exchange cabinet such that a noise level of 60 dB is measured at a distance of 1.5 meters from the assembled telecommunication exchange cabinet.

6. The assembled telecommunication exchange cabinet of claim 4, wherein the fan assembly is a low noise heat-sinking fan assembly, and the fan assembly is further mounted inside the assembled telecommunication exchange cabinet such that a noise level of 60 dB is measured at a distance of 1.5 meters from the assembled telecommunication exchange cabinet.

7. The assembled telecommunication exchange cabinet of claim 1, wherein the heat-sink device adopts an air convection principle such that cool air from outside enters the assembled telecommunication exchange cabinet from the bottom thereof and hot air from inside exits from the top thereof, and the temperature difference between the interior and exterior of the cabinet is effectively controlled, thereby when the heat-sink device has a transmitted power of 200 W, the temperature of the assembled telecommunication exchange cabinet is less than 50° C.

8. The assembled telecommunication exchange cabinet of claim 1, wherein the at least one spare battery is a valve regulated lead-acid battery.

9. The assembled telecommunication exchange cabinet of claim 1, wherein the at least one spare battery is a valve regulated Ni—Cd battery.

10. The assembled telecommunication exchange cabinet of claim 1, wherein the body further comprises a switching mode DC power supply device and a power distribution panel.

11. The assembled telecommunication exchange cabinet of claim 1, wherein the body is made of aluminum alloy and stainless steel.

12. The assembled telecommunication exchange cabinet of claim 11, wherein the body has a sandwiched aluminum board structure.

13. The assembled telecommunication exchange cabinet of claim 1, wherein a plurality of door latches are further installed on the body to lock the opposite side doors and the top cover respectively such that the left and right side doors and the top cover are adapted to be opened after the set of front doors is opened.

14. The assembled telecommunication exchange cabinet of claim 1, wherein the terminal boards are Cat.5 1800-pair fully gel-filled weather-resisting terminal boards.

15. The assembled telecommunication exchange cabinet of claim 1, wherein said terminal boards are Cat.5 2100-pair fully gel-filled weather-resisting terminal boards.

16. The assembled telecommunication exchange cabinet of claim 1, wherein said terminal boards are Cat.5 2400-pair fully gel-filled weather-resisting terminal boards.
